(19) United States
(12) Patent Application Publication
(10) Pub. No.: US 2024/0114795 A1
(43) Pub. Date: Apr. 4, 2024

(54) MEMS PIEZOELECTRIC SPEAKER

(71) Applicant: AAC Kaitai Technologies (Wuhan) CO., LTD, Wuhan (CN)

(72) Inventors: Yu Shen, Shenzhen (CN); Qiang Dan, Shenzhen (CN); Yiwei Zhou, Shenzhen (CN); Yang Li, Shenzhen (CN)

(21) Appl. No.: 18/092,942

(22) Filed: Jan. 4, 2023

Related U.S. Application Data
(63) Continuation of application No. PCT/CN2022/126561, filed on Oct. 21, 2022.

(30) Foreign Application Priority Data
Sep. 29, 2022 (CN) 202211203529.4

(51) Int. Cl. H10N 30/20; B81B 7/02; H10N 30/00; H10N 30/057; H10N 30/853

(52) U.S. Cl. CPC H10N 30/20; B81B 7/02; H10N 30/057; H10N 30/10513; H10N 30/853; B81B 2201/0257; B81B 2203/0315; B81B 2203/04

(57) ABSTRACT

The present invention provides a micro electromechanical system (MEMS), which includes: a base with a cavity, a vibration structure includes a structural layer, a piezoelectric composite layer and a flexible layer; the structural layer includes a structural slab, a structural fixing portion and a plurality of structural springs; the piezoelectric composite layer includes a piezoelectric film, a first electrode layer and a second electrode layer; the stress of the piezoelectric composite layer can be released through the elastic actions of the structural springs. In addition, the rigidity of the overall structure is ensured and will not be too low. Therefore, the sound pressure level of the MEMS piezoelectric loudspeaker is improved, and the THD is reduced to improve the performance of the MEMS piezoelectric loudspeaker.

### CROSS-REFERENCE TO RELATED APPLICATIONS

The application is a continuation of International Application No. PCT/CN2022/126561 filed on 10 21, 2022, which is incorporated herein by reference in its entireties.

### TECHNICAL FIELD

The present invention belongs to the acoustoelectric technical field, in particular, to a micro electromechanical system (MEMS) piezoelectric speaker.

### BACKGROUND

As one of main components of a mobile terminal such as a mobile phone and a tablet computer, an MEMS piezoelectric speaker is mainly used for converting an electrical signal into a sound signals, which is the key to achieving a human-computer interaction interface. Especially with the appearance of true wireless stereo (TWS) earphones, it is in an increasing urgent need for miniaturized and high-performance speakers. The MEMS piezoelectric speaker has become a main component combined with a traditional speaker and carrying high-frequency vibration due to its characteristics of miniaturization, lightweight, low power consumption and the like.

The existing MEMS piezoelectric speaker mainly includes a base, a structural layer fixed on the base, and a piezoelectric functional layer arranged on the structural layer. The piezoelectric functional layer includes a piezoelectric layer and electrode layers arranged on two opposite sides of the piezoelectric layer. Its working principle is that the piezoelectric functional layer will deform after being powered up, thus driving the overall structure to vibrate and produce sounds.

The existing MEMS piezoelectric speaker mainly has two structures: In one structure, the whole structural layer and the piezoelectric functional layer are directly stacked on the base in turn. This manner will lead to a large total harmonic distortion (THD) due to stress limitations of the process and the structures of various layers, and the ability to improve the sound pressure level (SPL) is limited. In the other structure, a middle drive area of a piezoelectric energy supply layer is directly arranged on a flexible film connected with the base. This manner will reduce the rigidity of the entire device and make the one-class resonant frequency of the speaker move to a low frequency. Correspondingly, a higher-class high resonant frequency will also move to the low frequency. As a result, the higher-order high resonant frequency appears in a human hearing range (20 Hz-20 kHz), which not only reduces the sound pressure level, but also increases the THD and affect the hearing.

### SUMMARY

The technical problem to be solved by the present invention is how to provide an MEMS piezoelectric speaker, so that the problems of a THD and a low sound pressure level due to the structural design of the existing MEMS piezoelectric speaker.

The present invention is realized as follows: a micro electromechanical system (MEMS) piezoelectric speaker, including a base and a vibration structure, the base is provided with a cavity;
the vibration structure includes a structural layer, a piezoelectric composite layer and a flexible layer which are stacked above the base in turn;
the structural layer includes a structural slab, a structural fixing portion surrounding the structural slab and spaced apart from the structural slab, and a plurality of structural springs connecting the structural slab and the structural fixing portion and having slits; the structural fixing portion is supported and fixed on the base; orthographic projections of the structural springs and the structural slab towards the base are completely located within a range of the cavity;
the piezoelectric composite layer includes a piezoelectric film, a first electrode layer formed on one side of the piezoelectric film close to the structural layer, and a second electrode layer formed on one side of the piezoelectric film away from the structural layer; mutually overlapping areas in orthographic projections of the piezoelectric film, the first electrode layer and the second electrode layer respectively towards the base are used as piezoelectric drive functional areas; the flexible layer is spaced apart from the structural layer in a stacking direction of the various layers of the vibration structure; and an orthographic projection of the flexible layer completely covers the slits of the plurality of structural springs.

Even further, the first electrode layer includes a first electrode functional portion fixed to the structural slab, a first electrode fixing portion fixed to the structural fixing portion, and a first electrode spring connecting the first electrode functional portion and the first electrode fixing portion.

Even further, the flexible layer covers one side of the second electrode layer away from the piezoelectric film, at least partially extends to the second electrode layer and a peripheral side of the piezoelectric film, and is fixed to a surface of one side of the first electrode layer away from the structural layer.

Even further, the piezoelectric film includes a piezoelectric functional portion fixed to the first electrode functional portion, a piezoelectric fixing portion fixed to the first electrode fixing portion, and a piezoelectric spring connecting the piezoelectric functional portion and the piezoelectric fixing portion.

Even further, the piezoelectric film, the first electrode layer and the structural layer have the same shapes and structures.

Even further, the flexible layer covers one side of the second electrode layer away from the piezoelectric film, at least partially extends to a peripheral side of the second electrode layer, and is fixed to a surface of one side of the piezoelectric film away from the structural layer.

Even further, the structural springs are of any one of a U-shaped structure, an annular structure and an S-shaped structure.

Even further, the piezoelectric film is made of any one of aluminum nitride, piezoelectric ceramic and zinc oxide.

Even further, the flexible layer is made of a high polymer material.

Even further, the high polymer is SU-8 photoresist or polyimide.

Compared with the prior art, the structural slab of the structural layer in the MEMS piezoelectric loudspeaker in this embodiment is connected to the structural fixing portion through the plurality of structural springs, and the mutually overlapping areas in the orthographic projections of the piezoelectric film, the first electrode layer and the second electrode layer in the piezoelectric composite layer respectively towards the base are used as piezoelectric drive functional areas. In this way, the stress of the piezoelectric composite layer can be released through the elastic actions of the structural springs. In addition, the rigidity of the overall structure is ensured and will not be too low. Therefore, the sound pressure level of the MEMS piezoelectric loudspeaker is improved, and the THD is reduced to improve the performance of the MEMS piezoelectric loudspeaker.

### BRIEF DESCRIPTION OF THE DRAWINGS

In order to explain the technical solutions of the embodiments of the present invention more clearly, the following will briefly introduce the accompanying drawings used in the embodiments. Apparently, the drawings in the following description are only some embodiments of the present invention. Those of ordinary skill in the art can obtain other drawings based on these drawings without creative work.

FIG. 1 is a schematic structural exploded diagram of a first kind of MEMS piezoelectric speaker provided by an embodiment of the present invention;

FIG. 2 is an overall schematic structural diagram of the first kind of MEMS piezoelectric speaker provided by an embodiment of the present invention;

FIG. 3 is a sectional view of line A-A in FIG. 2;

FIG. 4 is a schematic structural exploded diagram of a second kind of MEMS piezoelectric speaker provided by an embodiment of the present invention;

FIG. 5 is an overall schematic structural diagram of the second kind of MEMS piezoelectric speaker provided by an embodiment of the present invention;

FIG. 6 is a sectional view of line B-B in FIG. 5;

FIG. 7 is a schematic structural diagram of a second kind of structural layer provided by an embodiment of the present invention; and

FIG. 8 is a schematic structural diagram of a third kind of structural layer provided by an embodiment of the present invention.

### DETAILED DESCRIPTION OF THE EMBODIMENTS

In order to make the aims, technical solution and advantages of the present invention will be clearly, the present invention is further described below in combination with accompanying drawings and implementations. It should be understood that the specific embodiments described herein are intended only to explain the present invention and are not intended to define the present invention.

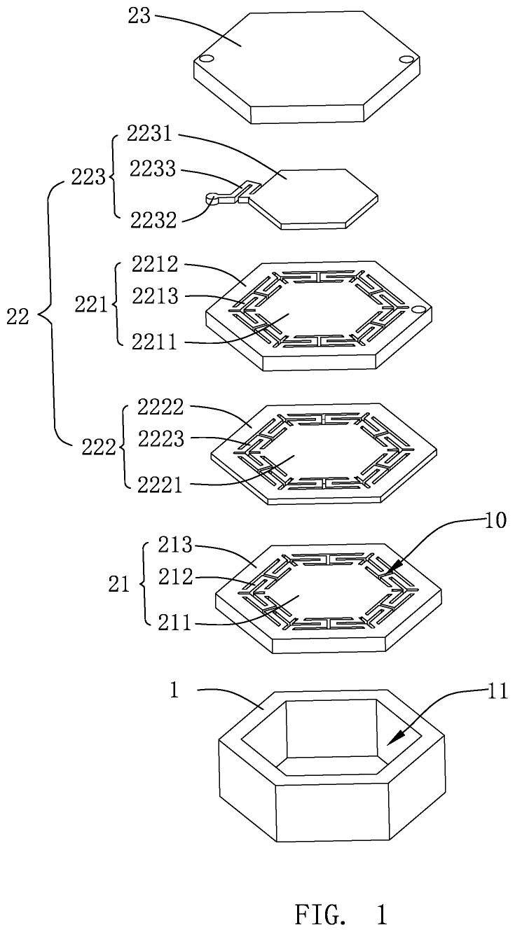

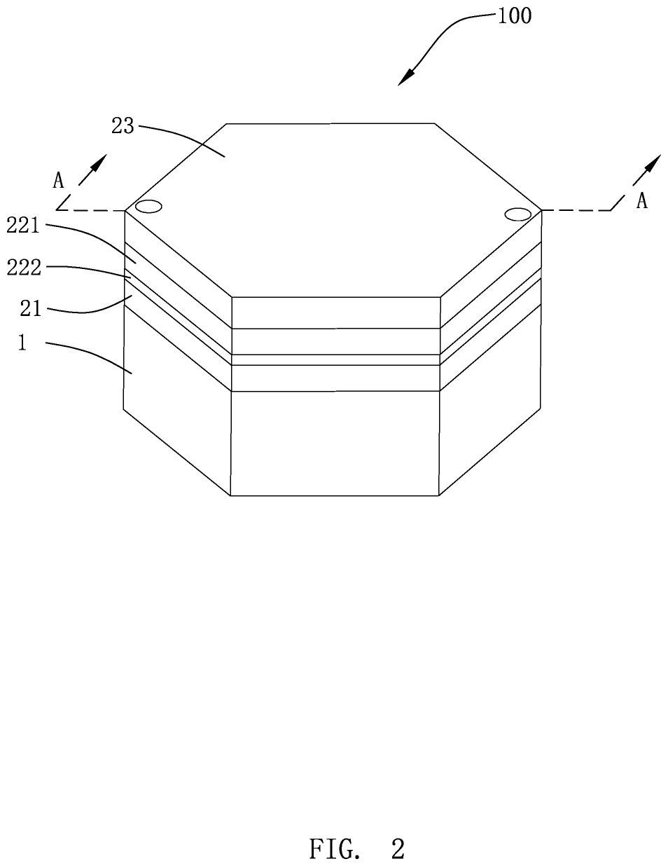

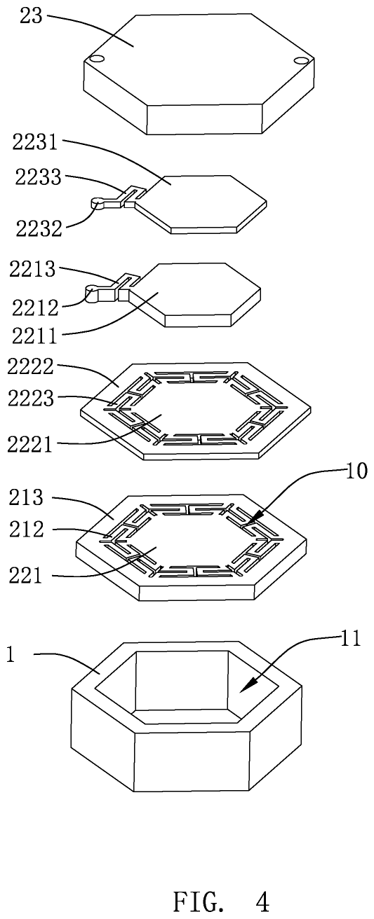

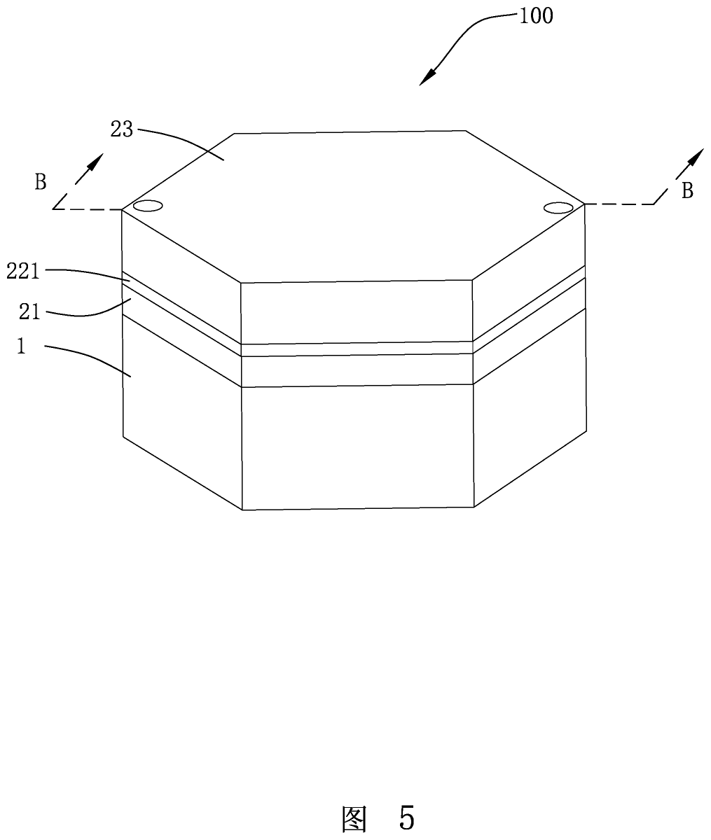

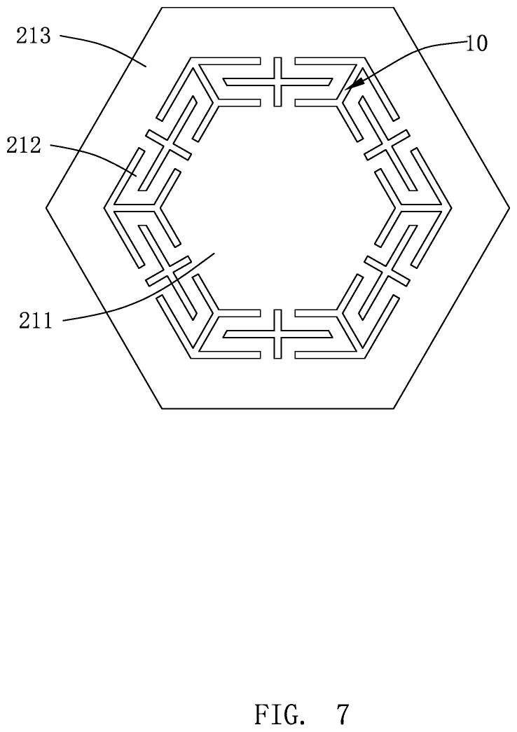

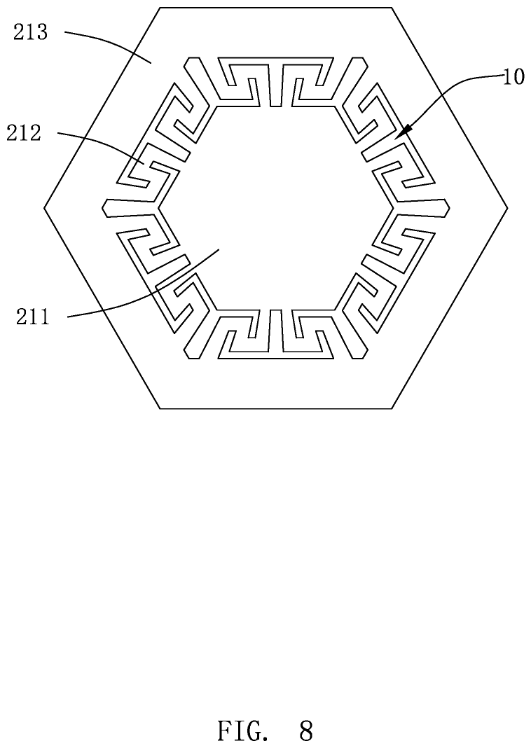

An embodiment of the present invention provides an MEMS piezoelectric speaker 100, including a base 1 and a vibration structure 2, referring to FIG. 1 to FIG. 8.

The base 1 is provided with a cavity 11. The vibration structure 2 includes a structural layer 21, a piezoelectric composite layer 22 and a flexible layer 23 which are stacked above the base 1 in turn.

The structural layer 21 includes a structural slab 211, a structural fixing portion 213 surrounding the structural slab 211 and spaced apart from the structural slab, and a plurality of structural springs 212 connecting the structural slab 211 and the structural fixing portion 213 and having slits 10. The structural fixing portion 213 is supported and fixed on the base 1, and orthographic projections of the structural springs 212 and the structural slab 211 towards the base 1 are completely located within a range of the cavity 11.

One end of each structural spring 212 is connected to the structural slab 211, and the other end is connected to the structural fixing portion 213. The structural springs 212 are of any one of a variety of structures, such as a U-shaped structure, an annular structure and an S-shaped structure. In this way, the rigidity of the overall structure can be improved through the elastic actions of the structural fixing portion 213 and the structural springs 212, without making the rigidity too low, thus improving the sound pressure level of the MEMS piezoelectric speaker and reducing the THD to improve the performance of the MEMS piezoelectric speaker.

The piezoelectric composite layer 22 includes a piezoelectric film 221, a first electrode layer 222 formed on one side of the piezoelectric film 221 close to the structural layer 21, and a second electrode layer 223 formed on one side of the piezoelectric film 221 away from the structural layer 21. Mutually overlapping areas in orthographic projections of the piezoelectric film 221, the first electrode layer 222 and the second electrode layer 223 respectively towards the base 1 are used as piezoelectric drive functional areas. The flexible layer 23 is spaced apart from the structural layer 21 in a stacking direction of the various layers of the vibration structure 2, and its orthographic projection covers the slits 10 of the plurality of structural springs 212.

The flexible layer 23 is spaced apart from the structural layer 21 in the stacking direction of the various layers of the vibration structure 2, and its orthographic projection completely covers the slits 10 between the plurality of structural springs 212, so that air can be prevented from leaking out from the slits 10.

The piezoelectric film 221 is made of any piezoelectric material, such as aluminum nitride (AlN), piezoelectric ceramic (PZT) and zinc oxide (ZnO). Of course, it can also be made of other materials according to actual needs. Descriptions thereof are omitted here.

The flexible layer 23 is made of a high polymer material. The high polymer is SU-8 photoresist or polyimide (PI). Of course, the flexible layer 23 can also be made of other high polymer materials according to actual needs. Descriptions thereof are omitted here.

The first electrode layer 222 includes a first electrode functional portion 2221 fixed to the structural slab 211, a first electrode fixing portion 2222 fixed to the structural fixing portion 213, and a first electrode spring 2223 connecting the first electrode functional portion 2221 and the first electrode fixing portion 2222.

An end face of the base 1 is a portion of one end of the base 1, which surrounds the cavity 11 and is also equivalent to a plane area at one end of the base 1.

There are a plurality of first electrode springs 2223, which are arranged around the first electrode functional portion 2221, and two adjacent first electrode springs are also spaced apart from each other. Of course, the first electrode layer 222 may not be provided with the first electrode fixing portion 2222 and the first electrode springs 2223 according to actual need, or the first electrode fixing portion 2222 may be set as a point portion, and there may be one first electrode spring 2223.

The piezoelectric film 221 includes a piezoelectric functional portion 2211 fixed to the first electrode functional portion 2221, a piezoelectric fixing portion 2212 fixed to the first electrode fixing portion 2221, and a piezoelectric spring 2213 connecting the piezoelectric functional portion 2211 and the piezoelectric fixing portion 2212. In this way, the rigidity of the overall structure can be improved through the elastic actions of the piezoelectric fixing portion 2212 and the piezoelectric spring 2213, without making the rigidity too low, thus improving the sound pressure level of the MEMS piezoelectric speaker and reducing the THD to improve the performance of the MEMS piezoelectric speaker.

Of course, the piezoelectric film 221 may also be provided with only the piezoelectric functional portion 2211, and provided with no piezoelectric fixing portion 2212 and the piezoelectric spring 2213. In this way, since no other structures are arranged at other positions except the piezoelectric drive functional area, the rigidity of the overall structure can be further reduced to adjust a first resonant frequency of the MEMS piezoelectric speaker 100 within a certain range, so as to expand an available audio frequency range.

The piezoelectric fixing portion 2212 may be of an annular structure, and there may be a plurality of corresponding piezoelectric springs 2213 arranged around the piezoelectric fixing portion 2212. At this time, the structure of the piezoelectric film 221 is similar or the same as that of the structural layer 21. Of course, the piezoelectric fixing portion 2212 may also be set as a point portion, and one piezoelectric spring 2213 may also be provided, which is similar or the same as the structural spring 212 in structure.

The piezoelectric film 221, the first electrode layer 222 and the structure layer 21 have the same shapes and structures.

The second electrode layer 223 includes a second electrode functional portion 2231 fixed to one side of the piezoelectric functional portion 2211 away from the first electrode functional portion 2221, a lead wire 2233 led out from a peripheral edge of the second electrode functional portion 2231, and a connection portion 2233 formed by one end of the lead wire 2233 away from the second electrode functional portion 2231. In this way, it is convenient to introduce electrical signals into the second electrode layer 223.

The second electrode fixing portion 2231 and the first electrode functional portion 2221 have the same shapes and structures.

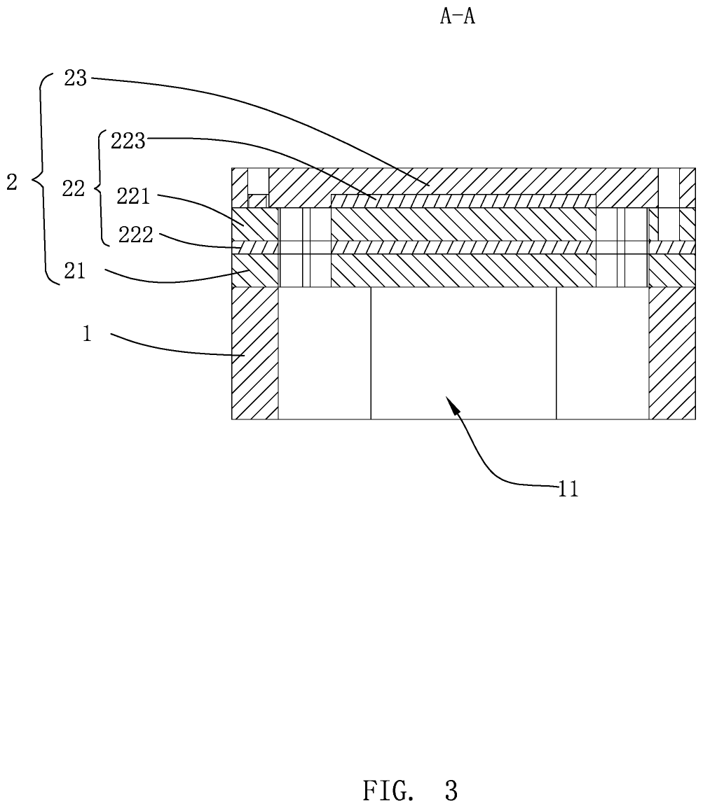

As shown in FIG. 3, the flexible layer 23 covers one side of the second electrode layer 223 away from the piezoelectric film 221, at least partially extends to a peripheral side of the second electrode layer 223, and is fixed on a surface of one side of the piezoelectric film 221 away from the structural layer 21.

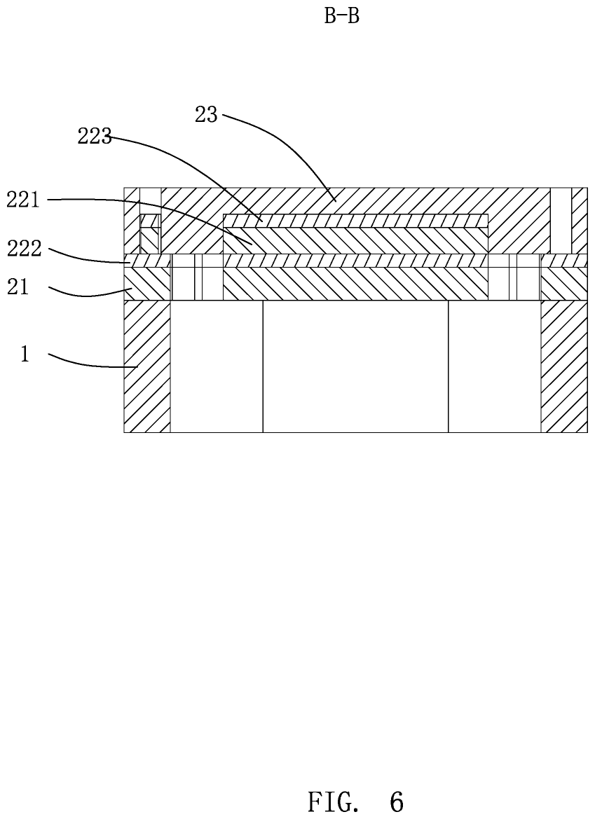

As shown in FIG. 6, the flexible layer 23 covers one side of the second electrode layer 223 away from the piezoelectric film 221, at least partially extends to the second electrode layer 223 and a peripheral side of the piezoelectric film 221, and is fixed to a surface of one side of the first electrode layer 222 away from the structural layer 21.

There may also be a plurality of structural layers 21 stacked in turn, such as two layers, three layers, and four layers. There may also be a plurality of piezoelectric composite layers 22 stacked in turn, such as two layers, three layers, and five layers.

Compared with the prior art, the structural slab 211 of the structural layer 21 in the MEMS piezoelectric loudspeaker 100 in this embodiment is connected to the structural fixing portion 213 through the plurality of structural springs 212, and the mutually overlapping areas in the orthographic projections of the piezoelectric film 221, the first electrode layer 222 and the second electrode layer 223 in the piezoelectric composite layer 22 respectively towards the base 1 are used as piezoelectric drive functional areas. In this way, the stress of the piezoelectric composite layer 22 can be released through the elastic actions of the structural springs 212. In addition, the rigidity of the overall structure is ensured and will not be too low. Therefore, the sound pressure level of the MEMS piezoelectric loudspeaker is improved, and the THD is reduced to improve the performance of the MEMS piezoelectric loudspeaker. That is, a larger boost level and available audios in a wider frequency range can be obtained. The stress of the piezoelectric composite layer 22 can be released, thus reducing the impact of the stress on the THD and reducing the power consumption of devices. At the same time, there will be no too many high-order resonant frequencies appearing in the audible frequency range, and an increase in the THD caused by too low rigidity can also be reduced.

The foregoing description is merely illustrative of the preferred embodiments of the present invention and is not intended to limit the present invention, but it is intended that any modifications, equivalents, substitutions, and modifications made within the spirit and principles of the present invention be embraced within the scope of the invention.

What is claimed is:

1. A micro electromechanical system (MEMS) piezoelectric speaker, comprising a base and a vibration structure, wherein
the base is provided with a cavity;
the vibration structure comprises a structural layer, a piezoelectric composite layer and a flexible layer which are stacked above the base in turn;
the structural layer comprises a structural slab, a structural fixing portion surrounding the structural slab and spaced apart from the structural slab, and a plurality of structural springs connecting the structural slab and the structural fixing portion and having slits; the structural fixing portion is supported and fixed on the base; orthographic projections of the structural springs and the structural slab towards the base are completely located within a range of the cavity;
the piezoelectric composite layer comprises a piezoelectric film, a first electrode layer formed on one side of the piezoelectric film close to the structural layer, and a second electrode layer formed on one side of the piezoelectric film away from the structural layer; mutually overlapping areas in orthographic projections of the piezoelectric film, the first electrode layer and the second electrode layer respectively towards the base are used as piezoelectric drive functional areas; the flexible layer is spaced apart from the structural layer in a stacking direction of the various layers of the vibration structure; and an orthographic projection of the flexible layer completely covers the slits of the plurality of structural springs.

2. The MEMS piezoelectric speaker according to claim 1, wherein the first electrode layer comprises a first electrode functional portion fixed to the structural slab, a first electrode fixing portion fixed to the structural fixing portion, and a first electrode spring connecting the first electrode functional portion and the first electrode fixing portion.

3. The MEMS piezoelectric speaker according to claim 2, wherein the flexible layer covers one side of the second electrode layer away from the piezoelectric film, at least partially extends to the second electrode layer and a peripheral side of the piezoelectric film, and is fixed to a surface of one side of the first electrode layer away from the structural layer.

4. The MEMS piezoelectric speaker according to claim 2, wherein the piezoelectric film comprises a piezoelectric functional portion fixed to the first electrode functional portion, a piezoelectric fixing portion fixed to the first electrode fixing portion, and a piezoelectric spring connecting the piezoelectric functional portion and the piezoelectric fixing portion.

5. The MEMS piezoelectric speaker according to claim 3, wherein the piezoelectric film, the first electrode layer and the structural layer have the same shapes and structures.

6. The MEMS piezoelectric speaker according to claim 4, wherein the piezoelectric film, the first electrode layer and the structural layer have the same shapes and structures.

7. The MEMS piezoelectric speaker according to claim 4, wherein the flexible layer covers one side of the second electrode layer away from the piezoelectric film, at least partially extends to a peripheral side of the second electrode layer, and is fixed to a surface of one side of the piezoelectric film away from the structural layer.

8. The MEMS piezoelectric speaker according to claim 1, wherein the structural springs are of any one of a U-shaped structure, an annular structure and an S-shaped structure.

9. The MEMS piezoelectric speaker according to claim 1, wherein the piezoelectric film is made of any one of aluminum nitride, piezoelectric ceramic and zinc oxide.

10. The MEMS piezoelectric speaker according to claim 1, wherein the flexible layer is made of a high polymer material.

11. The MEMS piezoelectric speaker according to claim 10, wherein the high polymer is SU-8 photoresist or polyimide.
